(19) United States
(12) Patent Application Publication
(10) Pub. No.: US 2005/0095855 A1
(43) Pub. Date: May 5, 2005

(54) Compositions and methods for the electroless deposition of NiFe on a work piece

(76) Inventors: John J. D'urso, Chandler, AZ (US); Jaynal A. Molla, Gilbert, AZ (US); Kelly W. Kyler, Mesa, AZ (US)

Correspondence Address: INGRASSIA FISHER & LORENZ, P.C., 7150 E. CAMELBACK, STE. 325, SCOTTSDALE, AZ, 85251, US

(21) Appl. No.: 10/702,909

(22) Filed: Nov. 5, 2003

(51) Int. Cl. B05D 5/12; C23C 18/34; C23C 18/36; H01L 21/44

(52) U.S. Cl. 438/678; 427/443.1; 427/58; 106/1.22; 106/1.27

(57) ABSTRACT

Methods and compositions are provided for the electroless deposition of NiFe on a work piece. A deposition solution for use in electroless deposition of NiFe on a work piece is formed from a nickel ion source, a ferrous iron source, a complexing agent, a reducing agent, and a pH adjusting agent. The deposition solution is substantially free from alkali metal ions.

A method for fabricating a flux concentrating system for use in a magnetoelectronics device begins by providing a work piece and forming an insulating material layer overlying the work piece. A trench is formed in an insulating layer and a barrier layer is deposited within the trench. A NiFe cladding layer is deposited overlying the barrier layer. After depositing the NiFe cladding layer, the insulating material layer proximate to the trench has a concentration of alkali metal ions less than about 1×10¹¹ atoms/cm².

### TECHNICAL FIELD

The present invention generally relates to the electrochemical deposition of nickel iron on a work piece, and more particularly relates to the electroless deposition of nickel iron on a work piece utilizing a substantially alkali metal-free deposition solution.

### BACKGROUND

Magnetoelectronics devices, spin electronics devices and spintronics devices are synonymous terms for devices that use the effects predominantly caused by electron spin. Magnetoelectronics effects are used in numerous information devices, and provide non-volatile, reliable, radiation resistant, and high-density data storage and retrieval. The numerous magnetoelectronics information devices include, but are not limited to, magnetic random access memory (MRAM), magnetic sensors and read/write heads for disk drives.

Generally, a magnetoelectronics information device is constructed with an array of magnetoelectronics elements (e.g., giant magnetoresistance (GMR) elements or magnetic tunnel junction (MTJ) elements) formed in a substrate that may also include a variety of semiconductor devices, such as, for example, MOSFETs. The magnetoelectronics elements are programmed by the magnetic field created from a current-carrying conductor. Typically, two current-carrying conductors, one formed underneath the magnetoelectronics element (the “digit line”) and one formed on top of the magnetoelectronics element (the “bit line”), are arranged in cross point matrix to provide magnetic fields for programming of the magnetoelectronics element.

Advanced semiconductor processes often use metal interconnects for the current-carrying conductors. One method of forming the metal interconnects is by a damascene or inlaid process during which a trench is patterned and etched in a dielectric layer, followed by the deposition of a metal layer, typically copper, within the trench. Flux concentrating systems often are formed proximate to the metal interconnect. Flux concentrating systems typically utilize cladding layers that are formed on three sides of the metal interconnect, leaving the side closest to the magnetoelectronics element without a cladding layer. In this manner, the cladding layers serve to concentrate the magnetic flux of the interconnect toward the magnetoelectronics element. Without cladding layers, high currents are required to achieve the desired magnetic field strength. These high currents may adversely affect nearby magnetoelectronics elements not being programmed. The cladding layers also serve to provide some shielding from external magnetic fields.

A frequently-used method for the fabrication of cladding layers includes the deposition of nickel-iron (NiFe) into a trench that has been etched in the dielectric layer that will be above or is below the magnetoelectronics element. NiFe is one of the more popular cladding materials because of its desirable soft magnetic properties. Typically, NiFe is deposited within the trench using plasma vapor deposition (PVD). However, the deposition of NiFe by PVD has proven unsatisfactory because the NiFe is not conformally deposited within the trench. Non-conformal deposition may result in the formation of voids within the trench. FIG. 1 is a representation of the non-conformal thickness of a NiFe layer deposited by PVD. FIG. 1 illustrates, in cross section, a dielectric layer 12 formed overlying a semiconductor work piece 10. A trench 14 has been formed in dielectric layer 12. The surface of dielectric layer 12 surrounding trench 14 is a field region 16. A field region is any adjacent element, character or surface that is elevated with respect to the trench. The field region is generally, but not necessarily, substantially planar. A NiFe layer 18 has been deposited overlying dielectric layer 12 by PVD. The NiFe layer overlying the field regions 16 is substantially uniform. However, the NiFe layer overlying the sidewalls of trench 14 is not uniform but, rather, has a greater thickness 20 proximate to the opening of trench 14 compared to a thickness 22 proximate to the bottom of trench 14.

Another method for depositing NiFe is electrodeposition (also known as electroplating). However, because of non-uniformities of electric current densities throughout the work piece during the electrodeposition process, which non-uniformities are particularly problematic in small-size features, it is difficult to obtain conformal sidewall coverage in the trenches. It also is difficult to obtain thicknesses suitable for the NiFe layer to serve as a layer.

In other applications, NiFe has been deposited by electrochemical deposition methods, such as electroless deposition Electroless deposition has been used successfully to achieve conformal deposition in features. However, electroless deposition methods typically utilize an electrochemical deposition solution that comprises a non-negligible amount of alkali metal ions, typically sodium (Na⁺) and potassium (K⁺) ions. Accordingly, such methods are undesirable for creating electronic devices, such as transistors, as even small amounts of Na⁺ or K⁺ ions in the devices can destroy them.

Accordingly, it is desirable to provide an improved method for depositing a NiFe layer for use in a flux concentrating system. In addition, it is desirable to provide a method for the electroless deposition of NiFe using an electrochemical deposition solution that is substantially alkali metal free. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and

FIG. 1 illustrates, in cross section, a work piece upon which a NiFe cladding layer has been deposited by plasma vapor deposition;

FIGS. 2-8 illustrate schematically, in cross section, a method for fabricating a cladded digit line in accordance with an exemplary embodiment ofthe invention; and

FIGS. 9-13 illustrate schematically, in cross section, a method for fabricating a cladded bit line in accordance with an exemplary embodiment of the invention.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

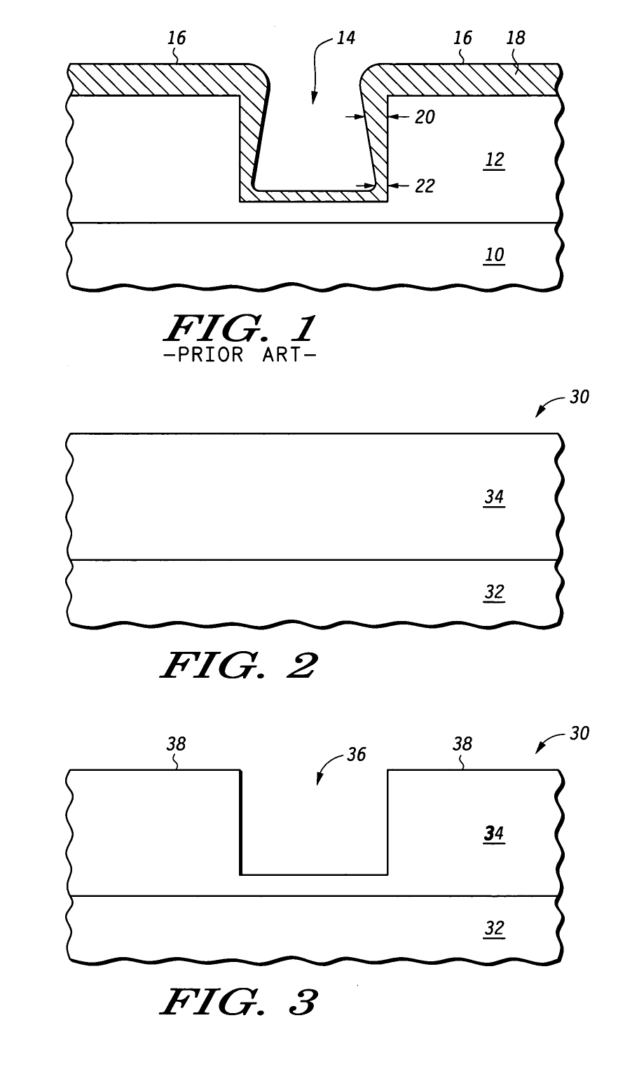

Turning now to the figures, FIGS. 2-8 illustrate a method for fabricating a cladded conductor, in particular, a cladded digit line, for use in a magnetoelectronics device in accordance with an exemplary embodiment of the present invention. The magnetoelectronics device may include a random access memory, magnetic sensors, inductors, read/write heads for disk drives, and any other device that utilizes the magnetic properties of a current-carrying conductor. Referring to FIG. 2, the method may begin by providing a work piece 30, such as, for example, a semiconductor wafer, having a substrate layer 32. Substrate layer 32 may comprise one layer or multiple layers and can include circuitry, such as sense amplifiers, transistors, and digital circuitry, which circuitry has not been shown for simplicity. A dielectric layer 34 may be deposited overlying substrate 32. Dielectric layer 34 typically is formed from any suitable type of insulative material, such as silicon oxide (SiO₂), tetraethyl orthosilicate (TEOS), silicon nitride (SiN) or other low-k dielectric material.

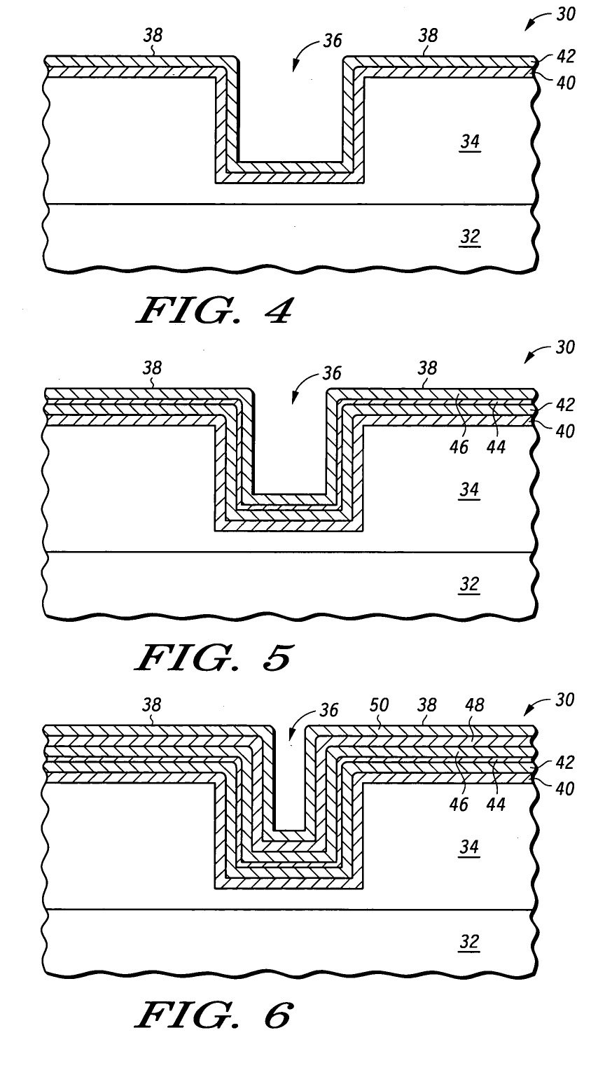

Referring to FIG. 3, a portion of dielectric layer 34 may be removed by patterning and etching to form one, or more than one, trench 36 within dielectric layer 34. Trench 36 is proximate to field regions 38. It will be appreciated that trench 36 may be of any length and height suitable to form an operative cladded conductor, as described in more detail below. Dielectric layer 34 may be etched utilizing standard etching techniques such as, for example, dry etch in plasma.

Referring to FIG. 4, a first conductive barrier layer 40 then may be formed overlying work piece 30 and within trench 36. First conductive barrier layer 40 prevents or minimizes the diffusion of copper through dielectric layer 34 and permits or facilitates the deposition of copper overlying dielectric layer 34. First conductive barrier layer 40 may comprise one conductive layer or more than one conductive layer. First conductive barrier layer 40 may be formed of tantalum (Ta), tantalum nitride (TaN), titanium (Ti), titanium nitride (TiN), tantalum silicon nitride (TaSiN), cobalt (Co), ruthenium (Ru), rhodium (Rh), palladium (Pd), or any other suitable metal that hinders or prevents copper from diffusing into or otherwise adversely reacting with surrounding materials. In a preferred embodiment of the present invention, first barrier layer 40 is formed of tantalum. First conductive barrier layer 40 may be deposited using physical vapor deposition (PVD), ionized metal plasma (IMP), chemical vapor deposition (CVD) or any other suitable technique known in the semiconductor industry.

In one exemplary embodiment of the present invention, a first seed layer 42 next may be deposited overlying first conductive barrier layer 40 and within trench 36 using PVD, IMP, CVD or any other suitable technique known in the semiconductor industry. First seed layer 42 may be formed of copper (Cu), ruthenium (Ru), cobalt (Co), palladium (Pd) or any other suitable metal. Preferably, first seed layer 42 is formed of copper.

Next, in accordance with another exemplary embodiment of the present invention, as illustrated in FIG. 5, an activation layer 44 then may be deposited overlying copper seed layer 42. Activation layer 44 serves as a catalyst to facilitate the subsequent deposition of the cladding layer, as described in more detail below. Growth of activation layers, such as activation layer 44, is well known in the semiconductor industry. Activation layer 44 may be deposited using an immersion deposition process, also known as a displacement deposition process, as is well known in the semiconductor industry or by any other suitable process. Preferably, activation layer 44 is formed of palladium, which will interact with copper seed layer 42 to form activation layer 44, although it will be appreciated that activation layer 44 may be formed of any suitable metal that will deposit overlying copper seed layer 42 and will facilitate the subsequent deposition of the cladding layer. It will be appreciated that first conductive barrier layer 40, first seed layer 42 and activation layer 44 can each be grown to a thickness suitable for the size of trench 36.

A NiFe cladding layer 46 then is deposited using electroless deposition The electroless deposition process utilizes an electroless deposition solution that is substantially alkaline metal-free. As used herein, the term “substantially alkali metal-free” deposition solution (or component thereof) or a deposition solution (or component thereof) “substantially free from alkali metal ions” means that the concentration of alkali metal ions in the deposition solution (or component thereof) is sufficiently low such that, upon deposition of NiFe cladding layer 46, the concentration of alkali metal ions in an insulating material layer proximate to the NiFe layer, such as dielectric layer 34, is no greater than 1×10¹² atoms/cm². In this manner, the concentration of alkali metal ions in the insulating material layer does not compromise the physical, chemical and/or electrical properties of the devices formed in semiconductor work piece 30. In a preferred embodiment of the present invention, the alkali metal ion concentration in an insulating material layer proximate to the NiFe layer, such as dielectric layer 34, is no greater than 1×10¹¹ atoms/cm². NiFe cladding layer 46 has a nickel concentration in the range of about 70 to about 90 atomic weight percent and a ferrous iron concentration in the range of about 10 to about 30 atomic weight percent, with an amount of boron and/or phosphorous that enhances the magnetic properties of the cladding layer. In one embodiment of the invention, the concentration of boron and/or phosphorous in NiFe cladding layer 46 is about 1 to about 15 atomic weight percent. In a preferred embodiment of the present invention, NiFe cladding layer 46 has a nickel concentration in the range of about 75 to about 78 atomic weight percent and a ferrous iron concentration of about 16 to about 18 atomic weight percent with about 5 to about 9 atomic weight percent of boron and/or phosphorous. In a more preferred embodiment of the invention, NiFe cladding layer 46 has a nickel concentration of about 75 atomic weight percent and a ferrous iron concentration of about 18 atomic weight percent with about 7 atomic weight percent of boron and/or phosphorous.

The electroless deposition solution is formulated from a source of nickel ions and a source of ferrous iron ions. The source of nickel ions may comprise nickel sulfamate, nickel chloride, nickel sulfate, and/or any other suitable nickel ion source. The source of ferrous iron ions may comprise iron sulfamate, iron chloride, iron sulfate, and/or any other suitable ferrous iron ion source. The electroless deposition solution may also be formulated from one or more complexing agents. The complexing agent may include glycine, tartaric acid, malic acid, citric acid, ammonium tartrate, ammonium citrate, ammonium acetate, acetic acid and/or any other suitable complexing agent known for use in electroless deposition processes. In a preferred embodiment of the present invention, the electroless deposition solution is formed from two complexing agents, glycine and tartaric acid. The electroless deposition solution also is formulated using one or more reducing agents. The reducing agent may include dimethylaminoborane (DMAB), morpholine borane (MPB), glyoxylic acid, ammonium hypophosphite and/or any other suitable reducing agent known for use in electroless deposition processes. In a preferred embodiment of the present invention, the electroless deposition solution is formulated using DMAB. The reducing agent and/or the complexing agent preferably contributes boron and/or phosphorous to NiFe cladding layer 46 to enhance the magnetic properties of the cladding layer, as described above.

In one exemplary embodiment of the present invention, to control the rate at which NiFe is deposited, the pH of the electroless deposition solution may be maintained in the range of about 7.5 to about 9.5. In a preferred embodiment of the present invention, the pH of the electroless deposition solution is in the range of about 7.8 to about 8.2. Thus, the electroless deposition may also be formulated using a pH adjusting agent to adjust the pH of the solution accordingly. Suitable pH adjusting agents may include electronic-grade tetramethylammonium hydroxide (TMAH), ammonium hydroxide, and/or any other suitable pH adjusting agent known for use in electroless deposition processes. In a preferred embodiment of the present invention, the electroless deposition solution is formulated utilizing TMAH as the pH adjusting agent.

The above-described components of the electroless deposition solution may be combined in any suitable order by any convenient method of mixing, such as, for example, by rapidly stirring with a mechanical stirrer or by agitating with a mechanical agitator. In one exemplary embodiment of the present invention, the electroless deposition solution may be formulated using nickel ions present in a concentration in the range of about 2.0 to 3.0 grams/liter, preferably about 2.2 to about 2.4 grams/liter, ferrous iron ions present in a concentration in the range of about 0.25 to about 0.40 grams/liter, preferably about 0.32 to about 0.36 grams/liter, glycine present in a concentration in the range of about 2.0 to about 10 grams/liter, preferably about 4.0 to about 5.0 grams/liter, tartaric acid present in a concentration in the range of about 20.0 to about 40.0 grams/liter, preferably about 25.0 to 30.0 grams/liter, DMAB present in a concentration in the range of about 1.5 to about 6.0 grams/liter, preferably 1.8 to about 2.2 grams/liter, and a 25% solution of TMAH present in an amount sufficient to adjust the pH of the electroless deposition solution to within a range of about 7.5 to about 9.5, preferably within a range of about 7.8 to about 8.2.

Referring again to FIG. 5, NiFe cladding layer 46 is formed by contacting activation layer 44 with the above-described electroless deposition solution that has a deposition temperature in the range of about 35° C. to about 65° C. In a preferred embodiment of the invention, the electroless deposition solution has a deposition temperature in the range of about 40° C. to 50° C. and, more preferably, the electroless deposition solution has a deposition temperature of about 41° C. The electroless deposition continues until the thickness of NiFe cladding layer 46 overlying field regions 38 is in the range of about 50 to about 400 angstroms, preferably in the range of about 150 to about 200 angstroms. By utilizing electroless deposition, the resulting NiFe cladding layer 46 is deposited conformally within trench 36, that is, NiFe cladding layer 46 has a uniform thickness overlying the bottom and sidewalls of trench 36, regardless of the size of trench 36.

In another exemplary embodiment of the present invention, as illustrated in FIG. 6, after deposition of NiFe cladding layer 46, a second conductive barrier layer 48 may be deposited overlying work piece 30. Second conductive barrier layer 48 serves to reduce or eliminate any intermetallic interferences between NiFe cladding layer 46 and a subsequently-formed copper interconnect layer that may detrimentally affect the magnetic properties of NiFe cladding layer 46. Second conductive barrier layer 48 may be formed of any of the materials described above to form first conductive barrier layer 40. Preferably, second conductive barrier layer 48 is formed of tantalum. Second barrier layer 48 may be deposited using PVD, IMP, CVD or any other suitable technique known in the semiconductor industry.

In one exemplary embodiment of the present invention, a second seed layer 50 next may be deposited overlying second barrier layer 48 and within trench 36. Second seed layer 50 may be formed of copper (Cu), ruthenium (Ru), cobalt (Co), palladium (Pd) or any other suitable metal. Preferably, second seed layer 50 is formed of copper. Second seed layer 50 may be formed using PVD, IMP, CVD or any other suitable technique known in the semiconductor industry. It will be appreciated that second conductive barrier layer 48 and second seed layer 50 can each be grown to a thickness suitable for the size of trench 36.

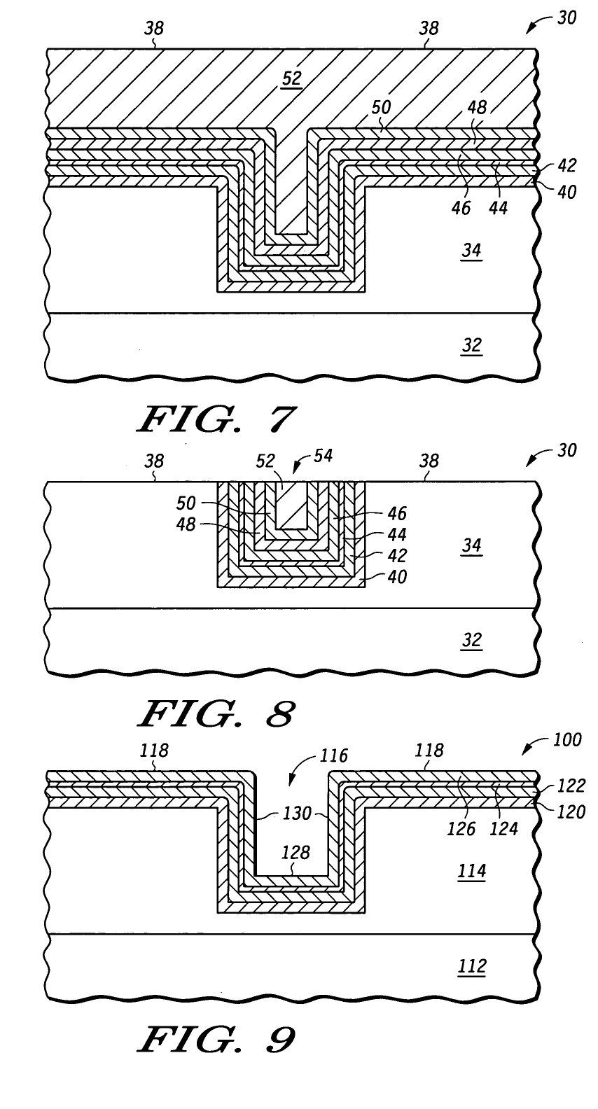

Next, as illustrated in FIG. 7, a conductive interconnect 52 is formed overlying work piece 30 and within trench 36. Conductive interconnect 52 may be formed using any suitable deposition process. In a preferred embodiment of the present invention, conductive interconnect 52 is deposited overlying work piece 30 and within trench 36 by electroplating. Conductive interconnect 52 may be comprised of copper, aluminum, gold, silver, and the like, or any combined alloy thereof. Preferably, second seed layer 50 and conductive interconnect 52 are formed of copper.

In one exemplary embodiment of the present invention, work piece 30 then may be subjected to an annealing process to stabilize conductive interconnect 52. Work piece 30 may be annealed at an anneal temperature in the range of about 100 to about 500° C., preferably in the range of about 200 to about 300° C. More preferably, the anneal temperature is about 250° C. Work piece 30 may be annealed for a period in the range of about 15 minutes to about one hour. Preferably, work piece 30 is annealed for about 30 minutes.

Referring to FIG. 8, after deposition and anneal of conductive interconnect 52, any excess metal overlying field regions 38, including conductive interconnect 52, second seed layer 50, second conductive barrier layer 48, NiFe cladding layer 46, activation layer 44, first seed layer 42 and first conductive barrier layer 40, and any other metallic layer, such as a second cladding layer, that has deposited overlying work piece 30 and within trench 36, may be removed from field regions 38 using any suitable process known in the semiconductor industry, such as by chemical mechanical planarization (CMP), dry or wet etching, and the like. According, as illustrated in FIG. 8, the above-described method results in the fabrication of a conductive digit line 54 comprising a conductive interconnect 52 and a flux concentrating system utilizing NiFe cladding layer 46 that has a uniform thickness surrounding three surfaces of conductive interconnect 52.

FIGS. 9-13 illustrate a method for fabricating a cladded conductor, in particular, a cladded bit line, for use in a magnetoelectronics device in accordance with another exemplary embodiment of the present invention. Referring to FIG. 9, the method may begin by providing a work piece 100, such as, for example, a semiconductor wafer, having a substrate layer 112. Substrate layer 112 may comprise one layer or multiple layers and can include circuitry, such as sense amplifiers, transistors, and digital circuitry, which circuitry has not been shown for simplicity. Substrate layer 112 further includes at least one magnetoelectronic element such as a giant magnetoresistance (GMR) element or a magnetic tunnel junction (MTJ) element, which element also has not been shown for simplicity. A dielectric layer 114 may be deposited overlying substrate 112. Dielectric layer 114 typically is formed from any suitable type of insulative oxide material, such as silicon oxide (SiO₂), tetraethyl orthosilicate (TEOS), or other low-K oxide dielectric material.

A portion of dielectric layer 114 may be removed by patterning and etching to form one, or more than one, trench 116 within dielectric layer 114. Trench 116 is proximate to field regions 118. It will be appreciated that trench 116 may be of any length and height suitable to form an operative cladded conductor, as described in more detail below. Dielectric layer 114 may be etched utilizing standard etching techniques such as, for example, dry etch in plasma.

The method further utilizes the steps described above with reference to FIGS. 4 and 5 to form a first conductive barrier layer 120, a first seed layer 122, a first activation layer 124 and a first NiFe cladding layer 126. First conductive barrier layer 120, first seed layer 122, first activation layer 124, and first NiFe cladding layer 126 may be formed using the same steps that were described above and may be formed from the same materials that were described above to form first conductive barrier layer 20, first seed layer 22, activation layer 24 and NiFe cladding layer 26, respectively. When formed within trench 116, first NiFe cladding layer 126 has a bottom surface 128 that overlies the bottom surface of trench 116 and sidewalls 130 that overlie the sidewalls of trench 116.

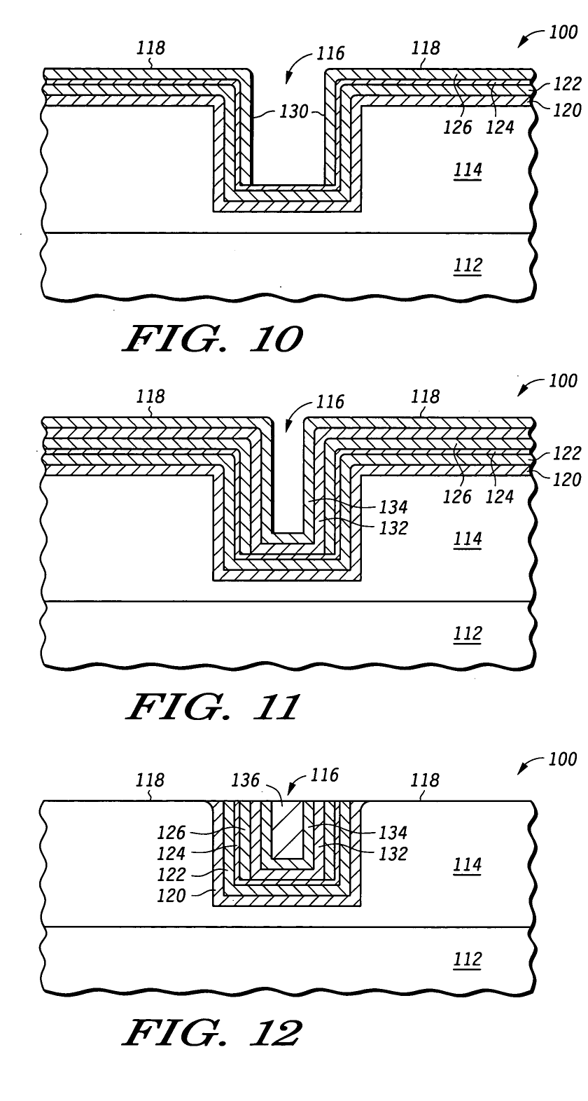

Referring to FIG. 10, after the deposition of first NiFe cladding layer 126 overlying work piece 100, the bottom surface 128 of first NiFe cladding layer 126 is removed from trench 116, leaving sidewalls 130 of first NiFe cladding layer 126. Bottom surface 128 is removed by any suitable method that is unidirectional such as, for example, sputtering.

Next, as illustrated in FIG. 11, a second conductive barrier layer 132 may be formed overlying work piece 100 and within trench 116. In one exemplary embodiment of the present invention, a second seed layer 134 also may be formed overlying second conductive barrier layer 132. Second conductive barrier layer 132 and second seed layer 134 may be formed using the same steps that were described above and may be formed from the same materials that were described above to form second conductive barrier layer 28 and second seed layer 30, respectively.

Referring now to FIG. 12, a conductive interconnect 136 is formed overlying work piece 100 and within trench 116. Conductive interconnect 136 may be formed by electroplating deposition or any other suitable deposition process. Conductive interconnect 136 may be comprised of copper or any alloy thereof Preferably, second seed layer 134 and conductive interconnect 136 are formed of copper. In one exemplary embodiment of the present invention, work piece 100 then may be subjected to an annealing process to stabilize conductive interconnect 136. Work piece 100 may be annealed at an anneal temperature in the range of about 100 to about 500° C., preferably in the range of about 200 to about 300° C. More preferably, the anneal temperature is about 250° C. Work piece 100 may be annealed for a period in the range of about 15 minutes to about one hour. Preferably, work piece 100 is annealed for about 30 minutes.

After the deposition and anneal of conductive interconnect 136, any excess metal overlying field regions 118, including conductive interconnect 136, second seed layer 134, second conductive barrier layer 132, first NiFe cladding layer 126, first activation layer 124, first seed layer 122 and first conductive barrier layer 120, and any other metallic layer, such as a second cladding layer, that has deposited overlying work piece 100 and within trench 116, may be removed from field regions 118 using any suitable process known in the semiconductor industry, such as by chemical mechanical planarization (CMP), dry or wet etching, or the like.

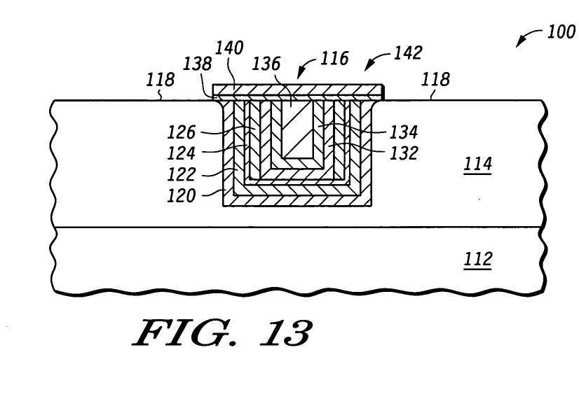

In one exemplary embodiment of the present invention, referring to FIG. 13, a second or “top” activation layer 138 then may be deposited overlying conductive interconnect 136. As used herein, the term “top” means a position or point proximate to the opening of trench 116. Second activation layer 138 serves as a catalyst to facilitate the subsequent deposition of a top cladding layer, as described in more detail below. Second activation layer 138 may be deposited using an immersion deposition process, also known as a displacement deposition process, as is well known in the semiconductor industry or by any other suitable process. Preferably, second activation layer 138 is formed of palladium, which will interact with conductive interconnect 136 to form second activation layer 138, although it will be appreciated that second activation layer 138 may be formed of any suitable metal that will deposit overlying conductive interconnect 136 and will facilitate the subsequent deposition of the cladding layer.

Next, a second or “top” NiFe cladding layer 140 then is deposited overlying second activation layer 138 by electroless deposition using the electroless deposition solution disclosed above. Second NiFe cladding layer 140 may have the same composition and be formed from the same materials as described above for first NiFe cladding layer 126 and NiFe cladding layer 46. The deposition of NiFe using the above-described electroless deposition solution is selective to metal, that is, it will deposit on the activated copper layers but will not deposit on dielectric material layer 114. In this manner, a self-aligned second NiFe cladding layer 140 may be deposited overlying copper interconnect layer 136 to form a bit line 142 without the need for an additional masking and patterning step. Because second NiFe cladding layer 140 is self-aligned, shorting of bit line 142 with an adjacent bit line due to a common electrical contact from a misaligned top cladding layer is unlikely to occur.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

1. A deposition solution for use in electroless deposition of NiFe on a work piece, the deposition solution formulated from:
a nickel ion source;
a ferrous iron ion source;
a complexing agent;
a reducing agent; and
a pH adjusting agent,
wherein the deposition solution is substantially free from alkali metal ions.

2. The deposition solution for use in electroless deposition of NiFe on a work piece of claim 1, wherein said nickel ion source is selected from the group comprising nickel sulfamate, nickel chloride and nickel sulfate.

3. The deposition solution for use in electroless deposition of NiFe on a work piece of claim 1, wherein said ferrous iron ion source is selected from the group comprising iron sulfamate, iron chloride and iron sulfate.

4. The deposition solution for use in electroless deposition of NiFe on a work piece of claim 1, wherein said complexing agent is selected from the group comprising glycine, tartaric acid, malic acid, citric acid, ammonium tartrate, ammonium citrate, ammonium acetate, and acetic acid.

5. The deposition solution for use in electroless deposition of NiFe on a woik piece of claim 1, wherein said reducing agent is selected from the group comprising dimethylaminoborane, morpholine borane, glyoxylic acid and ammonium hypophosphite.

6. The deposition solution for use in electroless deposition of NiFe on a work piece of claim 1, wherein the deposition solution has a pH in the range of about 7.5 to about 9.5.

7. The deposition solution for use in electroless deposition of NiFe on a work piece of claim 6, wherein the deposition solution has a pH in the range of about 7.8 to about 8.2.

8. The deposition solution for use in electroless deposition of NiFe on a work piece of claim 1, wherein said pH adjusting agent is selected from the group comprising electronic-grade tetramethylammonium hydroxide and ammonium hydroxide.

9. A method for the electroless deposition of NiFe on a work piece:
formulating a substantially alkali metal-free deposition solution from the following components:
a nickel ion source;
a ferrous iron ion source;
a complexing agent;
a reducing agent; and
a pH adjusting agent,
elevating a temperature of said substantially alkali metal-free deposition solution to a temperature in the range of about 35° C. to about 65° C.; and
contacting the work piece with said substantially alkali metal-free deposition solution.

10. The method for the electroless deposition of NiFe on a work piece of claim 9, wherein the step of formulating comprises formulating a substantially alkali metal-free deposition solution from said nickel ion source that is selected from the group comprising nickel sulfamate, nickel chloride and nickel sulfate.

11. The method for the electroless deposition of NiFe on a work piece of claim 9, wherein the step of formulating comprises formulating a substantially alkali metal-free deposition solution from said ferrous iron ion source that is selected from the group comprising iron sulfamate, iron chloride and iron sulfate.

12. The method for the electroless deposition of NiFe on a work piece of claim 9, wherein the step of formulating comprises formulating a substantially alkali metal-free deposition solution from said complexing agent that is selected from the group comprising glycine, tartaric acid, malic acid, citric acid, ammonium tartrate, ammonium citrate, ammonium acetate, and acetic acid.

13. The method for the electroless deposition of NiFe on a work piece of claim 9, wherein the step of formulating comprises formulating a substantially alkali metal-free deposition solution from said reducing agent that is selected from the group comprising dimethylaminoborane, morpholine borane, glyoxylic acid and ammonium hypophosphite.

14. The method for the electroless deposition of NiFe on a work piece of claim 9, wherein the step of formulating comprises formulating said substantially alkali metal-free deposition solution to have a pH in the range of about 7.5 to about 9.5.

15. The method for the electroless deposition of NiFe on a work piece of claim 14, wherein the step of formulating comprises formulating said substantially alkali metal-free deposition solution to have a pH in the range of about 7.8 to about 8.2.

16. The method for the electroless deposition of NiFe on a work piece of claim 9, wherein the step of formulating said substantially alkali metal-free deposition solution from a pH adjusting agent comprises formulating said substantially alkali metal-free deposition solution from said pH adjusting agent selected from the group comprising electronic-grade tetramethylammonium hydroxide and ammonium hydroxide.

17. A method for fabricating a flux concentrating system for use in a magnetoelectronics device, the method comprising the steps of:
providing a work piece;
forming an insulating material layer overlying said work piece;
removing a portion of said insulating material to form a trench in said insulating layer;
depositing a barrier layer within said trench; and
depositing a NiFe cladding layer overlying said barrier layer,
wherein, after the step of depositing a NiFe cladding layer, said insulating material layer proximate to said trench has a concentration of alkali metal ions less than about 1×10¹¹ atoms/cm².

18. The method for fabricating a flux concentrating system for use in a magnetoelectronics device of claim 17, the method further comprising the step of forming a seed layer after the step of depositing a barrier layer and before the step of depositing a NiFe cladding layer.

19. The method for fabricating a flux concentrating system for use in a magnetoelectronics device of claim 18, wherein the step of forming a seed layer comprises forming a copper seed layer.

20. The method for fabricating a flux concentrating system for use in a magnetoelectronics device of claim 18, the method further comprising the step of forming an activation layer after the step of forming a seed layer and before the step of depositing a NiFe cladding layer.

21. The method for fabricating a flux concentrating system for use in a magnetoelectronics device of claim 20, the step of forming an activation layer comprising the step of forming an activation layer of palladium.

22. The method for fabricating a flux concentrating system for use in a magnetoelectronics device of claim 17, wherein the step of depositing a barrier layer comprises the step of depositing a barrier layer formed of at least one material selected from the group comprising tantalum, tantalum nitride, titanium, titanium nitride, tantalum silicon nitride, cobalt, ruthenium, rhodium, and palladium.

23. The method for fabricating a flux concentrating system for use in a magnetoelectronics device of claim 17, wherein the step of depositing a NiFe cladding layer comprises the step of depositing a NiFe cladding layer by electroless deposition.

24. The method for fabricating a flux concentrating system for use in a magnetoelectronics device of claim 23, wherein the step of depositing a NiFe cladding layer by electroless deposition comprises the step of depositing utilizing an electroless deposition solution formed from a nickel ion source, a ferrous iron ion source, a complexing agent, a reducing agent, and a pH adjusting agent, wherein the electroless deposition solution is substantially free from alkali metal ions.

25. The method for fabricating a flux concentrating system for use in a magnetoelectronics device of claim 23, wherein the step of depositing a NiFe cladding layer by electroless deposition comprises the step of depositing utilizing an electroless deposition solution having a pH in the range of about 7.5 to about 9.5.

26. The method for fabricating a flux concentrating system for use in a magnetoelectronics device of claim 25, wherein the step of depositing utilizing an electroless deposition solution comprises the step of depositing utilizing an electroless deposition solution having a pH in the range of about 7.8 to about 8.2.

27. The method for fabricating a flux concentrating system for use in a magnetoelectronics device of claim 17, wherein the step of depositing a NiFe cladding layer comprises the step of depositing said NiFe cladding layer to a thickness in the range of about 50 to about 400 angstroms.

28. The method for fabricating a flux concentrating system for use in a magnetoelectronics device of claim 17, wherein the step of depositing a NiFe cladding layer comprises the step of depositing said NiFe cladding layer having a composition of about 70 to about 90 atomic weight percent of nickel, about 10 to about 30 atomic weight percent of ferrous iron and about 1 to about 15 atomic weight percent of at least one of boron and phosphorous.

29. A method for fabricating a digit line for use in a magnetoelectronics device, the method comprising the steps of:
providing a substrate;
forming an insulating material layer overlying said substrate;
removing a portion of said insulating material layer to form a trench in said insulating material layer;
depositing a first barrier layer within said trench;
depositing by electroless deposition a NiFe cladding layer overlying said barrier layer;
depositing a second barrier layer overlying said NiFe cladding layer; and
forming a conductive interconnect overlying said second barrier layer and within said trench;
wherein, after the step of depositing by electroless deposition a NiFe cladding layer, said insulating material layer proximate to said trench has a concentration of alkali metal ions less than about 1×10¹¹ atoms/cm².

30. The method for fabricating a digit line for use in a magnetoelectronics device of claim 29, the method further comprising the step of forming a seed layer overlying said first barrier layer before the step of depositing by electroless deposition a NiFe cladding layer.

31. The method for fabricating a digit line for use in a magnetoelectronics device of claim 29, the method further comprising the step of forming a seed layer overlying said second barrier layer before the step of forming a conductive interconnect.

32. The method for fabricating a digit line for use in a magnetoelectronics device of claim 30, the method further comprising the step of forming an activation layer overlying said seed layer before the step of depositing a NiFe cladding layer.

33. The method for fabricating a digit line for use in a magnetoelectronics device of claim 29, wherein the step of depositing a barrier layer comprises the step of depositing a barrier layer formed of at least one material selected from the group comprising tantalum, tantalum nitride, titanium, titanium nitride, tantalum silicon nitride, cobalt, ruthenium, rhodium, and palladium.

34. The method for fabricating a digit line for use in a magnetoelectronics device of claim 29, wherein the step of depositing by electroless deposition a NiFe cladding layer comprises the step of depositing utilizing an electroless deposition solution formed from a nickel ion source, a ferrous iron ion source, a complexing agent, a reducing agent, and a pH adjusting agent, wherein the electroless deposition solution is substantially free from alkali metal ions.

35. The method for fabricating a digit line for use in a magnetoelectronics device of claim 34, wherein the step of depositing utilizing an electroless deposition solution comprises the step of depositing utilizing said electroless deposition solution that has a pH in the range of about 7.5 to about 9.5.

36. The method for fabricating a digit line for use in a magnetoelectronics device of claim 29, wherein the step of depositing by electroless deposition a NiFe cladding layer comprises the step of depositing a NiFe cladding layer until said NiFe cladding layer has a thickness in the range of about 50 to about 400 angstroms.

37. The method for fabricating a digit line for use in a magnetoelectronics device of claim 29, wherein the step of depositing by electroless deposition a NiFe cladding layer comprises the step of depositing a NiFe cladding layer having a composition of about 70 to about 90 atomic weight percent of nickel, about 10 to about 30 atomic weight percent of iron and about 1 to about 15 atomic weight percent of at least one of boron and phosphorous.

38. A method for fabricating a bit line for use in a magnetoelectronics device, the method comprising the steps of:
providing a substrate;
forming an insulating material layer overlying said substrate;
removing a portion of said insulating material layer to form a trench in said insulating material layer, said trench having a bottom surface and sidewalls integrally connected thereto;
depositing a first barrier layer overlying said bottom surface and said sidewalls of said trench; and
depositing by electroless deposition a first NiFe cladding layer overlying said barrier layer, said first NiFe cladding layer having a bottom surface and sidewalls integrally connected thereto, wherein said bottom surface of said NiFe cladding layer is proximate to said bottom surface of said trench;
removing said bottom surface of said first NiFe cladding layer;
depositing a second barrier layer overlying said sidewalls of said NiFe cladding layer and overlying said bottom surface of said trench;
forming a conductive interconnect overlying said second barrier layer and within said trench; and
depositing by electroless deposition a second NiFe cladding layer overlying said conductive interconnect, wherein, after the step of depositing by electroless deposition a first NiFe cladding layer, said insulating material layer proximate to said trench has a concentration of alkali metal ions less than about 1×10¹¹ atoms/cm².

39. The method for fabricating a bit line for use in a magnetoelectronics device of claim 38, the method further comprising the step of forming a seed layer overlying said first barrier layer before the step of depositing by electroless deposition a first NiFe cladding layer.

40. The method for fabricating a bit line for use in a magnetoelectronics device of claim 38, the method further comprising the step of forming a seed layer overlying said second barrier layer before the step of forming a conductive interconnect.

41. The method for fabricating a bit line for use in a magnetoelectronics device of claim 39, the method further comprising the step of forming an activation layer overlying said seed layer before the step of depositing by electroless deposition a first NiFe cladding layer.

42. The method for fabricating a bit line for use in a magnetoelectronics device of claim 38, wherein the step of depositing a first barrier layer and the step of depositing a second barrier layer comprise the step of depositing a barrier layer formed of at least one material selected from the group comprising tantalum, tantalum nitride, titanium, titanium nitride, tantalum silicon nitride, cobalt, ruthenium, rhodium, and palladium.

43. The method for fabricating a bit line for use in a magnetoelectronics device of claim 38, wherein the step of depositing by electroless deposition a first NiFe cladding layer comprises the step of depositing utilizing an electroless deposition solution formed from a nickel ion source, a ferrous iron ion source, a complexing agent, a reducing agent, and a pH adjusting agent, wherein the electroless deposition solution is substantially free from alkali metal ions.

44. The method for fabricating a bit line for use in a magnetoelectronics device of claim 43, wherein the step of depositing utilizing an electroless deposition solution comprises the step of depositing utilizing said electroless deposition solution that has a pH in the range of about 7.5 to about 9.5.

45. The method for fabricating a bit line for use in a magnetoelectronics device of claim 38, wherein the step of depositing by electroless deposition a first NiFe cladding layer comprises the step of depositing said first NiFe cladding layer until said first NiFe cladding layer has a thickness in the range of about 50 to about 400 angstroms.

46. The method for fabricating a bit line for use in a magnetoelectronics device of claim 38, wherein the step of depositing a first NiFe cladding layer comprises the step of depositing a cladding layer having a composition of about 70 to about 90 atomic weight percent nickel, about 10 to about 30 atomic weight percent iron and about 1 to about 15 atomic weight percent of at least one of boron and phosphorous.

47. The method for fabricating a bit line for use in a magnetoelectronics device of claim 38, wherein the step of removing comprises sputtering said bottom surface of said first NiFe cladding layer.

48. The method for fabricating a bit line for use in a magnetoelectronics device of claim 38, wherein the step of depositing by electroless deposition a second NiFe cladding layer comprises the step of depositing utilizing an electroless deposition solution formed from a nickel ion source, a ferrous iron ion source, a complexing agent, a reducing agent, and a pH adjusting agent, wherein the electroless deposition solution is substantially free from alkali metal ions.

49. The method for fabricating a bit line for use in a magnetoelectronics device of claim 48, wherein the step of depositing utilizing an electroless deposition solution comprises the step of depositing utilizing said electroless deposition solution that has a pH in the range of about 7.5 to about 9.5.

50. The method for fabricating a bit line for use in a magnetoelectronics device of claim 38, wherein the step of depositing by electroless deposition a second NiFe cladding layer comprises the step of depositing said second NiFe cladding layer until said second NiFe cladding layer has a thickness in the range of about 50 to about 400 angstroms.

51. The method for fabricating a bit line for use in a magnetoelectronics device of claim 38, wherein the step of depositing a second NiFe cladding layer comprises the step of depositing said second NiFe cladding layer having a composition of about 70 to about 90 atomic weight percent of nickel, about 10 to about 30 atomic weight percent of iron and about 1 to about 15 atomic weight percent of at least one of boron and phosphorous.

52. The method for fabricating a bit line for use in a magnetoelectronics device of claim 38, the method further comprising forming an activation layer overlying said conductive interconnect before the step of depositing by electroless deposition a second NiFe cladding layer.
